(19) United States
(12) Patent Application Publication
(10) Pub. No.: US 2010/0301389 A1
(43) Pub. Date: Dec. 2, 2010

(54) ESD PROTECTION STRUCTURE

(76) Inventors: Vadim A. Kushner, Tempe, AZ (US); Amaury Gendron, Scottsdale, AZ (US); Chai Ean E. Gill, Chandler, AZ (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 12/474,443

(22) Filed: May 29, 2009

(51) Int. Cl. H01L 29/73

(52) U.S. Cl. 257/173; 257/E29.175; 361/56

(57) ABSTRACT

An electrostatic discharge protection structure includes a first vertical bipolar junction transistor; a second vertical bipolar junction transistor, wherein the second vertical bipolar junction transistor has a common collector with the first vertical bipolar junction transistor, and the common collector has a first conductivity; a horizontal bipolar junction transistor wherein the collector of the horizontal bipolar junction transistor has a second conductivity that is a different conductivity than the first conductivity, and the base of the horizontal bipolar junction transistor is electrically coupled to the common collector of the first vertical bipolar junction transistor and the second vertical bipolar junction transistor; a first avalanche diode electrically coupled to the base and the collector of the first vertical bipolar junction transistor; and a second avalanche diode electrically coupled to the base and the collector of the second vertical bipolar junction transistor.

### BACKGROUND

1. Field

This disclosure relates generally to integrated circuits and, more particularly, to ESD protection for inputs and outputs of integrated circuits.

2. Related Art

Electrostatic discharge (ESD) has been a continuing problem for integrated circuits. ESD generally occurs due to human contact but can be from other sources. In either case, integrated circuits nearly always have some form of ESD protection to reduce the likelihood of the integrated circuit being permanently damaged by an ESD event. These events can be either a positive voltage or a negative voltage relative to an input and/or output (I/O) pad. An ESD event is simulated as a pulse according to one or more of several models. Exemplary models currently in use are the Human Body Model (HBM), the Machine Model (MM), and the Charge Device Model (CDM). The first objective is to provide the specified protection for each I/O pad. Exceeding the specified protection can also be beneficial because the ultimate objective is simply to avoid a failure due to an ESD event. It is desirable that this protection not adversely impact performance which can occur by adding too much capacitance to the I/O pad or otherwise affecting the desired performance of the functional circuit coupled to the I/O pad. Also, it is desirable to avoid requiring excessive chip area for the circuit that is providing the ESD protection. ESD protection can become complex. It can be crowded in the area where the I/O pads are located so space can be at a premium in those locations.

Accordingly, there is a need for ESD protection that improves upon one or more of the issues raised above.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 is a cross section of a semiconductor device useful for ESD protection according to a first embodiment;

FIG. 2 is a circuit diagram showing functionality of the semiconductor device of FIG. 1 for the case of a positive ESD event; and

FIG. 3 FIG. 2 is a circuit diagram showing functionality of the semiconductor device of FIG. 1 for the case of a negative ESD event.

### DETAILED DESCRIPTION

In one aspect, an ESD protection structure that is coupled to an I/O pad includes an efficient way of providing ESD protection for both positive and negative ESD events. A large commonality of elements is achieved in providing protection for both positive and negative ESD events while achieving ESD protection for the I/O pad. This is better understood by reference to the following specification and drawings.

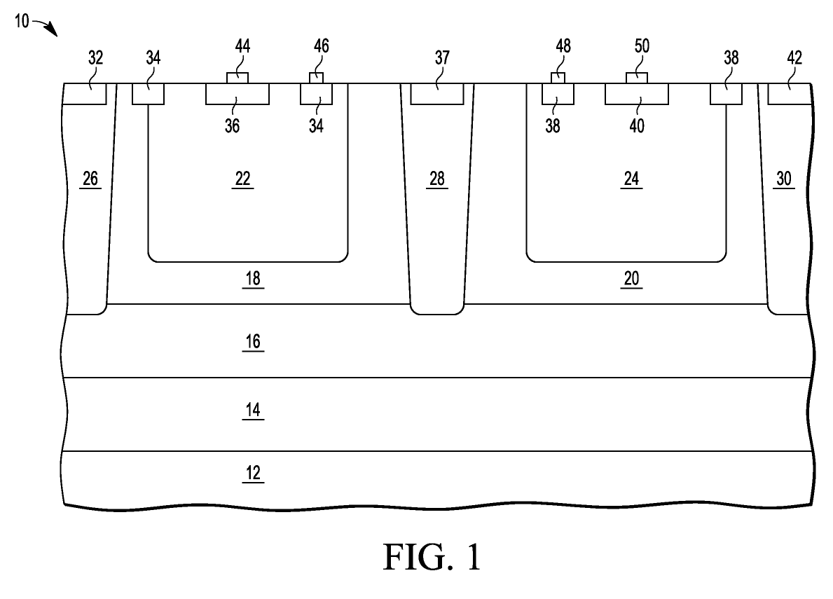

Shown in FIG. 1 is a semiconductor device 10 comprising a substrate 12 that has had an epitaxial layer grown over it. Substrate 12 may be of silicon heavily doped to P type and the epitaxial layer may also be silicon. Formed in the epitaxial layer is a P layer 14 that is lightly doped over substrate 12, an N layer 16 that is heavily doped over P layer 14, connection regions 26, 28, and 30 of N type that are heavily doped and extend from a top surface of semiconductor device 10 to penetrate into N layer 16, a P region 18 from the top surface to N layer 16 and between connection regions 26 and 28, a P region 20 from the top surface to N layer 16 and between connection regions 28 and 30, a P region 22 (which may also be called a well region) formed within P region 18 from the top surface and distanced from N layer 16, a P region 24 (which may also be called a well region) within region 20 from the top surface and distanced from N layer 16, a heavily doped N region 32 at the top surface and within connection region 26, an N-type emitter 36 substantially centered in region 22 and at the top surface, a P region 34 that is heavily doped for receiving a contact and is annular so surrounds emitter 36, a heavily doped N region 42 at the top surface and within connection region 30, an N-type emitter 40 substantially centered in region 24 and at the top surface, a P region 38 that is heavily doped for receiving a contact and is annular so surrounds emitter 40, an N region 37 at the top surface and in connection region 28 that is heavily doped, a contact pad 44 on emitter 36, a contact pad 46 on region 34, a contact pad 48 on region 38, and a contact pad 50 on region 40. Regions 18 and 20 are more lightly doped than regions 22 and 24. Layers 14 and 16 and regions 18 and 20 are doped during the epitaxial growth process. Connection regions 26, 28, and 30, P regions 22 and 24, N regions 32 and 42, P regions 34 and 38, and emitter regions 36 and 40 are formed by implanting.

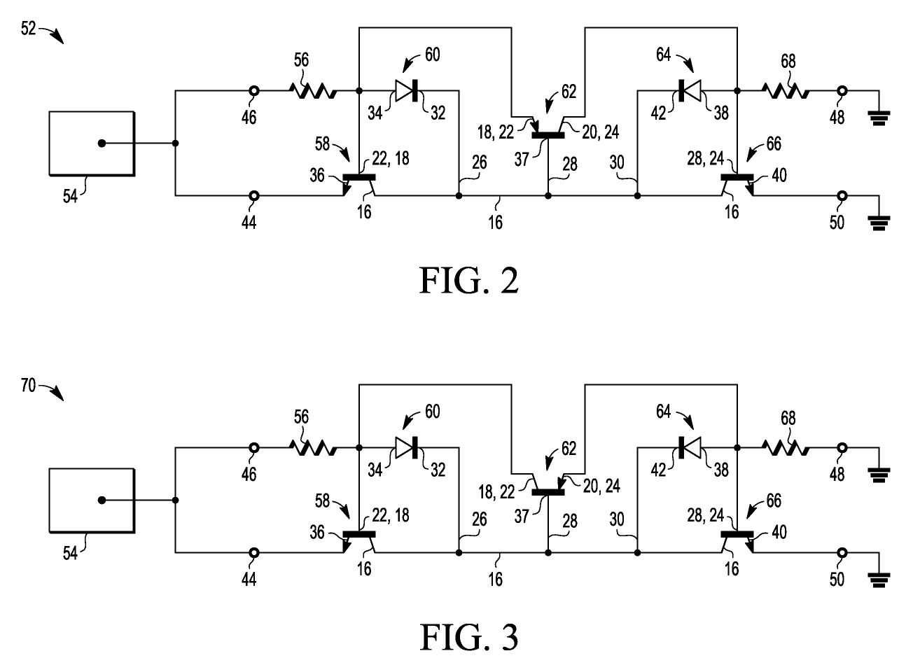

Shown in FIG. 2 is a circuit 52 showing semiconductor device 10 and an I/O pad 54 in circuit diagram form for the case where a positive ESD event is received at I/O pad 54. Circuit 52 shows a resistor 56, an NPN transistor 58, an avalanche diode 60, a PNP transistor 62, an avalanche diode 64, an NPN transistor 66, and a resistor 68. Contact pads 46 and 44 are connected together and to I/O pad 54. Resistor 56, which is a parasitic resistor, has a first terminal connected to contact pad 46 and a second terminal. Transistor 58 has an emitter connected to contact pad 44, a base connected to the second terminal of resistor 56, and a collector. N layer 16 and region 28 serve as the collector for transistor 58. The base includes regions 22 and 18 between region 34 and N layer 16. Thus there is resistance, which is represented by resistor 56, between contact pad 46 and its function as a base. Avalanche diode 60 has a first terminal which is in common with the base of transistor 58 and thus also has resistance represented by resistor 56. A second terminal of avalanche diode 60 is in part provided by region 32. The portion of region 34 closest to region 32 as well as region 32 influence the operation of avalanche diode 60 which is present at the interface between P region 18 and connection region 26 which is N-type. The second terminal of avalanche diode 60 is connected to the collector of transistor 58 by N connection region 26 contacting N layer 16. Contact pad 46 is a base contact for transistor 58. Transistor 62 has an emitter formed from P regions 18 and 22, a base formed from regions 28 and 37 which are N type, and a collector formed from P regions 20 and 24. Thus transistor 62 has its emitter connected to base of transistor 58 and the first terminal of avalanche diode 60, its base connected to the collectors of transistors 58 and 66 through connection region 28 which contacts N layer 16, and its collector connected to a first terminal of avalanche diode 64 and a base of transistor 66. Contact pads 48 and 50 are connected to ground. Resistor 68, which is a parasitic resistor, has a first terminal connected to contact pad 48 and a second terminal. Transistor 66 has an emitter connected to contact pad 50, a base connected to the second terminal of resistor 68, and a collector. N layer 16 and region 18 serve as the collector for transistor 66. The base includes regions 20 and 24 between region 38 and N layer 16. Thus there is resistance, which is represented by resistor 68, between contact pad 48 and its function as a base. Avalanche diode 64 has a first terminal which is in common with the base of transistor 66 and thus also has resistance represented by resistor 68. A second terminal of avalanche diode 64 is in part provided by region 42. The portion of region 38 closest to region 42 as well as region 42 influence the operation of avalanche diode 64 which is present at the interface between P region 20 and connection region 30. The second terminal of avalanche diode 64 is connected to the collector of transistor 66 by N connection region 30 contacting N layer 16.

In the case of a positive ESD event, which in this described example may be a HBM, MM, or CDM pulse applied at I/O pad 54. This causes avalanche diode 60 to be forward biased causing a PN junction drop which is often called a Vbe drop which thus causes transistor 62 to be conductive. The base of transistor 66 and the first terminal of avalanche diode 64 are held near ground, but due to parasitic resistor 68, some voltage can be maintained at the base of transistor 66. With avalanche diode 60 passing the ESD event voltage, minus a forward biased PN junction drop, to region 42, as the second terminal of avalanche diode 64, through layer 16 and first terminal 48 being held relatively low, avalanche diode 64 breaks down. Thus current is passed through resistor 68 from avalanche diode 64 and transistor 62 to cause transistor 66 to be conductive. With transistor 66 being conductive, most of the current arising from the ESD event passes through transistor 66. As can be seen in FIG. 1, the collector and base of transistor 66 are quite large and effective at dissipating power. There is little voltage drop through forward biased avalanche diode 32 so little power is dissipated there. Transistor 62 is kept conductive because of the forward biased emitter-base junction. The result that transistors 62 and 66 are conductive for as long as the ESD event lasts.

For a negative ESD event analogous to the described positive event, which in this described example may be a HBM, HH, or CDM negative pulse applied at I/O pad 54. Circuit 70, which is the equivalent circuit for this situation, is shown in FIG. 3. The only difference from FIG. 2 is that the emitter and collector of transistor 62 are reversed. Structurally, the emitter and collector are the same so the operation is symmetrical. Upon the application of the negative voltage to I/O 54, avalanche diode 60 will be reverse-biased and avalanche diode 64 will be forward biased causing the PN junction voltage drop. This forward-biased PN junction drop causes transistor 62 to become conductive. When reverse biased avalanche diode 60 breaks down, current is supplied to resistor 56 and thus causing transistor 58 to become conductive. Similar to the operation for transistors 62 and 66 for the positive ESD event, transistors 58 and 62 remain conductive with transistor 58 carrying most of the current which it is designed to dissipate.

The structure shown in FIG. 1 that provides the functionality of FIGS. 2 and 3 is beneficial in providing efficient use of common collector connection using layer 16 as well as convenient contacts with avalanche diodes 60 and 64 and the base of transistor 62. Although the reverse biased avalanche diode in breakdown dissipates some power, the current is low compared to that of the primary dissipation transistors 58 or 66. The avalanche diodes are beneficial in keeping the dissipation transistors conductive by providing extra current through the parasitic resistors. Transistors 58 and 66 being vertical transistors allows for more power dissipation capability without increasing area. Transistor 62 being a horizontal bipolar transistor provides for efficient symmetry so that it can be used for both negative and positive ESD events. There is also efficient use of the various structures in that nearly all of the various structures are used for dissipating both the negative and positive ESD events. The change in the PNP base width allows for holding voltage control but also controls the ON resistance of the ESD structure. Similar control of holding voltage can be achieved by changing the distance between the NPN base to common collector and it also controls ON resistance of the ESD structure. The structure parameters can be optimized by modifying the doping profiles of P-wells 22 and 24, P-epi regions 18 and 20 and N-buried layer 16 and N-region 28 to achieve desired range of holding voltage. The holding voltage is desired to be high to avoid latch-up issues when device triggers and enters deep snapback of the ESD structure. The proposed design delivers holding voltages twice higher than in previous art and contains very little snapback voltage since the holding voltage is close to the trigger voltage.

Dimensions of the various features are variable and may be chosen based on the particular performance desired. Important performance issues for transistors and 58 and 66 relate to snap back and trigger voltage (also called breakdown voltage) for avalanche diodes 60 and 64. Layer 14 may be 5 microns thick. Layer 16 may be 2 microns thick. The thickness of regions 22 and 24 may be 1.8 microns. The vertical spacing between layers 22 and 16 may be 1.2 microns. Similarly, the vertical spacing between region 24 and layer 16 may be 1.2 microns. These thicknesses for layers 14 and 16 and regions 22 and 24 are measured vertically as shown in FIG. 1. The lateral distance between the edge of region 34 that is nearest to region 32 and the edge of connection region 26 may be between 0.5 micron and 5 microns. Similarly, the lateral distance between the edge of region 38 that is nearest to region 42 and the edge of connection region 30 may be between 0.5 micron and 5 microns. The lateral width of connection region 28 near the surface, which is the base dimension of transistor 62, may be between 0.5 micron and 20 microns. The lateral distance between connection region 28 and region 24 near the surface may be between 1.5 microns and 7 microns. Similarly, the lateral distance between connection region 28 and region 22 near the surface may be between 1.5 and 7 microns. It is beneficial for the distance between layer 16 and region 22 to be less than the lateral distances between region 22 and regions 26 and 28. Similarly, it is beneficial for the distance between layer 16 and region 24 to be less than the lateral distance between region 24 and regions 30 and 28. This is to avoid or at least reduce adverse affects of a parasitic lateral NPN transistors formed from regions 26, 18, 22, and/or regions 30, 20, 24, and 40 and/or 18, 22, 36 and/or regions 28, 20, 24, and 40.

The semiconductor substrate described herein can be any semiconductor material or combinations of materials, such as gallium arsenide, silicon germanium, silicon-on-insulator (SOI), silicon, monocrystalline silicon, the like, and combinations of the above.

By now it should be appreciated that there has been provided an electrostatic discharge protection structure. The structure includes a first vertical bipolar junction transistor. The structure further includes a second vertical bipolar junction transistor, wherein the second vertical bipolar junction transistor has a common collector with the first vertical bipolar junction transistor and the common collector has a first conductivity. The structure further includes a horizontal bipolar junction transistor wherein a collector of the horizontal bipolar junction transistor has a second conductivity that is a different conductivity than the first conductivity and a base of the horizontal bipolar junction transistor is electrically coupled to the common collector of the first vertical bipolar junction transistor and the second vertical bipolar junction transistor. The structure further includes a first avalanche diode electrically coupled to a base and the collector of the first vertical bipolar junction transistor. The structure further includes a second avalanche diode electrically coupled to a base and the collector of the second vertical bipolar junction transistor. The structure may be further characterized by the base of the first vertical bipolar junction transistor being capable of being one of the emitter and collector of the horizontal bipolar junction transistor. The structure may be further characterized by the base of the second vertical bipolar junction transistor being capable of being one of the collector and emitter of the horizontal bipolar junction transistor. The structure may be further characterized by an anode of the first avalanche diode being part of the base of the first vertical bipolar junction transistor. The structure may be further characterized by the common collector of the first vertical bipolar junction transistor and the second vertical bipolar junction transistor being coupled to a cathode of the first avalanche diode through a first contact region having the first conductivity and being coupled to a cathode of the second avalanche diode through a second contact region having the first conductivity. The structure may be further characterized by an anode of the second avalanche diode being part of the base of the second vertical bipolar junction transistor. The structure may be further characterized by the common collector of the first vertical bipolar junction transistor and the second vertical bipolar junction transistor being coupled to the cathode of the first avalanche diode through a first contact region having the first conductivity and being coupled to the cathode of the second avalanche diode through a second contact region having the first conductivity. The structure may be further characterized by the base of the first vertical bipolar junction transistor comprising a first well having the second conductivity, wherein a first portion of the base of the first vertical bipolar junction transistor is within the first well and a second portion of the base of the first vertical bipolar junction transistor extends outside the first well. The structure may be further characterized by the base of the second vertical bipolar junction transistor comprising a second well having the second conductivity, wherein a first portion of the base of the second vertical bipolar junction is within the second well and a second portion of the base of the second vertical bipolar junction extends outside the second well.

Described also is an electrostatic discharge protection structure. The structure further includes a first bipolar junction transistor having a collector with a first conductivity type and a base. The structure further includes a second bipolar junction transistor having a collector with the first conductivity type and a base, wherein the collector of the first bipolar junction transistor is electrically coupled to the collector of the second vertical bipolar junction transistor. The structure further includes a third bipolar junction transistor, wherein a collector of the third bipolar junction transistor has a second conductivity type, wherein the second conductivity type is different than the first conductivity type and a base of the third bipolar junction transistor has the first conductivity type, wherein the base is electrically coupled to the collector of the first bipolar junction transistor and the collector of the second bipolar junction transistor. The structure further includes a first avalanche diode electrically coupled to the base and the collector of the first bipolar junction transistor. The structure further includes a second avalanche diode electrically coupled to the base and the collector of the second bipolar junction transistor. The structure may be further characterized by the collector of the first bipolar junction transistor and the collector of the second bipolar junction transistor comprising a layer having the first conductivity, wherein the layer is over a substrate having the second conductivity. The structure may be further characterized by the layer being coupled to the cathode of a first avalanche diode and the cathode of a second avalanche diode. The structure may be further characterized by an anode of the first avalanche diode being part of the base of the first bipolar junction transistor and an anode of the second avalanche diode is part of the base of the second bipolar junction transistor. The structure may be further characterized by the layer being coupled to a cathode of the first avalanche diode through a first contact region having the first conductivity and is coupled to a cathode of the second avalanche diode through a second contact region having the first conductivity. The structure may be further characterized by the base of the first bipolar junction transistor comprising a first well having the second conductivity, wherein a first portion of the base is within the first well and a second portion of the base extends outside the first well, and the base of the second bipolar junction transistor comprising second well having the second conductivity, wherein a first portion of the base is within the second well and a second portion of the base extends outside the second well. The structure may be further characterized by the first bipolar junction transistor comprising a first vertical bipolar transistor, the second bipolar junction transistor comprising a second vertical bipolar transistor, and the third bipolar junction transistor comprising a horizontal bipolar transistor.

Also described is an electrostatic discharge protection electrostatic discharge protection structure. The structure includes a first vertical bipolar junction transistor. The structure further includes a second vertical bipolar junction transistor, wherein the second vertical bipolar junction transistor shares a collector with the first vertical bipolar junction transistor and the collector is a buried layer having a first conductivity. The structure further includes a bipolar junction transistor wherein a collector of the horizontal bipolar junction transistor has a second conductivity that is a different conductivity than the first conductivity and a base of the horizontal bipolar junction transistor is electrically coupled to the buried layer. The structure further includes a first avalanche diode electrically coupled to a base and the collector of the first vertical bipolar junction transistor. The structure further includes a second avalanche diode electrically coupled to a base and the collector of the second vertical bipolar junction transistor. The structure may be further characterized by an anode of the first avalanche diode being part of the base of the first vertical bipolar junction transistor and an anode of the second avalanche diode being part of the base of the second vertical bipolar junction transistor. The structure may be further characterized by the base of the first vertical bipolar junction transistor comprising a first well having the second conductivity, wherein a first portion of the base of the first vertical bipolar junction transistor is within the first well and a second portion of the base of the first vertical bipolar junction transistor extends outside the first well, and the base of the second vertical bipolar junction transistor comprising second well having the second conductivity, wherein a first portion of the base the second vertical bipolar junction transistor is within the second well and a second portion of the base the second vertical bipolar junction transistor extends outside the second well. The structure may be further characterized by the base of the first vertical bipolar junction transistor being capable of being one of the emitter and collector of the horizontal bipolar junction transistor.

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

Although the invention has been described with respect to specific conductivity types or polarity of potentials, skilled artisans appreciated that conductivity types and polarities of potentials may be reversed. For example the transistor types would be reversed by reversing the conductivity types used in forming the circuit elements used to achieve the desired function.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. For example, a particular ESD event was described but other ESD events may also be applied. Also the avalanche diodes may be implemented as zener diodes. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed is:

1. An electrostatic discharge protection structure comprising:
a first vertical bipolar junction transistor;
a second vertical bipolar junction transistor, wherein:
the second vertical bipolar junction transistor has a common collector with the first vertical bipolar junction transistor; and
the common collector has a first conductivity;
a horizontal bipolar junction transistor wherein:
a collector of the horizontal bipolar junction transistor has a second conductivity that is a different conductivity than the first conductivity; and
a base of the horizontal bipolar junction transistor is electrically coupled to the common collector of the first vertical bipolar junction transistor and the second vertical bipolar junction transistor;
a first avalanche diode electrically coupled to a base and the collector of the first vertical bipolar junction transistor; and
a second avalanche diode electrically coupled to a base and the collector of the second vertical bipolar junction transistor.

2. The electrostatic discharge protection structure of claim 1, wherein the base of the first vertical bipolar junction transistor is capable of being one of the emitter and collector of the horizontal bipolar junction transistor.

3. The electrostatic discharge protection structure of claim 1, wherein the base of the second vertical bipolar junction transistor is capable of being one of the collector and emitter of the horizontal bipolar junction transistor.

4. The electrostatic discharge protection structure of claim 1, wherein an anode of the first avalanche diode is part of the base of the first vertical bipolar junction transistor.

5. The electrostatic discharge protection structure of claim 4, wherein the common collector of the first vertical bipolar junction transistor and the second vertical bipolar junction transistor is coupled to a cathode of the first avalanche diode through a first contact region having the first conductivity and is coupled to a cathode of the second avalanche diode through a second contact region having the first conductivity.

6. The structure of claim 4, wherein an anode of the second avalanche diode is part of the base of the second vertical bipolar junction transistor.

7. The electrostatic discharge protection structure of claim 6, wherein the common collector of the first vertical bipolar junction transistor and the second vertical bipolar junction transistor is coupled to the cathode of the first avalanche diode through a first contact region having the first conductivity and is coupled to the cathode of the second avalanche diode through a second contact region having the first conductivity.

8. The electrostatic discharge protection structure of claim 1, wherein the base of the first vertical bipolar junction transistor comprises a first well having the second conductivity, wherein a first portion of the base of the first vertical bipolar junction transistor is within the first well and a second portion of the base of the first vertical bipolar junction transistor extends outside the first well.

9. The electrostatic discharge protection structure of claim 8, wherein the base of the second vertical bipolar junction transistor comprises a second well having the second conductivity, wherein a first portion of the base of the second vertical bipolar junction is within the second well and a second portion of the base of the second vertical bipolar junction extends outside the second well.

10. An electrostatic discharge protection structure comprising:
a first bipolar junction transistor having a collector with a first conductivity type and a base;
a second bipolar junction transistor having a collector with the first conductivity type and a base, wherein the collector of the first bipolar junction transistor is electrically coupled to the collector of the second vertical bipolar junction transistor;
a third bipolar junction transistor, wherein:
a collector of the third bipolar junction transistor has a second conductivity type, wherein the second conductivity type is different than the first conductivity type; and
a base of the third bipolar junction transistor has the first conductivity type, wherein the base is electrically coupled to the collector of the first bipolar junction transistor and the collector of the second bipolar junction transistor; and
a first avalanche diode electrically coupled to the base and the collector of the first bipolar junction transistor; and
a second avalanche diode electrically coupled to the base and the collector of the second bipolar junction transistor.

11. The electrostatic discharge protection structure of claim 10, wherein the collector of the first bipolar junction transistor and the collector of the second bipolar junction transistor comprise a layer having the first conductivity, wherein the layer is over a substrate having the second conductivity.

12. The electrostatic discharge protection structure of claim 11, wherein the layer is coupled to the cathode of a first avalanche diode and the cathode of a second avalanche diode.

13. The electrostatic discharge protection structure of claim 12, wherein an anode of the first avalanche diode is part of the base of the first bipolar junction transistor and an anode of the second avalanche diode is part of the base of the second bipolar junction transistor.

14. The electrostatic discharge protection structure of claim 13, wherein the layer is coupled to a cathode of the first avalanche diode through a first contact region having the first conductivity and is coupled to a cathode of the second avalanche diode through a second contact region having the first conductivity.

15. The electrostatic discharge protection structure of claim 10, wherein
the base of the first bipolar junction transistor comprises a first well having the second conductivity, wherein a first portion of the base is within the first well and a second portion of the base extends outside the first well; and
the base of the second bipolar junction transistor comprises second well having the second conductivity, wherein a first portion of the base is within the second well and a second portion of the base extends outside the second well.

16. The electrostatic discharge protection structure of claim 15, wherein:
the first bipolar junction transistor comprises a first vertical bipolar transistor;
the second bipolar junction transistor comprises a second vertical bipolar transistor; and
the third bipolar junction transistor comprises a horizontal bipolar transistor.

17. An electrostatic discharge protection electrostatic discharge protection structure comprising:
a first vertical bipolar junction transistor;
a second vertical bipolar junction transistor, wherein:
the second vertical bipolar junction transistor shares a collector with the first vertical bipolar junction transistor; and
the collector is a buried layer having a first conductivity;
a bipolar junction transistor wherein:
a collector of the horizontal bipolar junction transistor has a second conductivity that is a different conductivity than the first conductivity; and
a base of the horizontal bipolar junction transistor is electrically coupled to the buried layer;
a first avalanche diode electrically coupled to a base and the collector of the first vertical bipolar junction transistor; and
a second avalanche diode electrically coupled to a base and the collector of the second vertical bipolar junction transistor.

18. The electrostatic discharge protection structure of claim 17, wherein:
an anode of the first avalanche diode is part of the base of the first vertical bipolar junction transistor; and
an anode of the second avalanche diode is part of the base of the second vertical bipolar junction transistor.

19. The electrostatic discharge protection structure of claim 18, wherein:
the base of the first vertical bipolar junction transistor comprises a first well having the second conductivity, wherein a first portion of the base of the first vertical bipolar junction transistor is within the first well and a second portion of the base of the first vertical bipolar junction transistor extends outside the first well; and
the base of the second vertical bipolar junction transistor comprises second well having the second conductivity, wherein a first portion of the base the second vertical bipolar junction transistor is within the second well and a second portion of the base the second vertical bipolar junction transistor extends outside the second well.

20. The electrostatic discharge protection structure of claim 19, wherein the base of the first vertical bipolar junction transistor is capable of being one of the emitter and collector of the horizontal bipolar junction transistor.
